(19) United States
(12) Patent Application Publication
(10) Pub. No.: US 2026/0305122 A1
(43) Pub. Date: Oct. 1, 2026

(54) DISPLAY APPARATUS

(71) Applicant: LG Display Co., Ltd., Seoul (KR)

(72) Inventor: Jang JO, Paju-si (KR)

(21) Appl. No.: 19/363,932

(22) Filed: Oct. 21, 2025

(30) Foreign Application Priority Data
Mar. 27, 2025 (KR) 10-2025-0039586

(51) Int. Cl. H10K 59/80; H10K 59/35

(52) U.S. Cl. CPC H10K 59/80518; H10K 59/353; H10K 59/876

(57) ABSTRACT

A display apparatus including a substrate including a plurality of sub-pixels, a first electrode disposed in each of the sub-pixels, a light-emitting layer disposed on the first electrode, a second electrode disposed on the light-emitting layer, and a cavity control layer disposed between the first electrode and the substrate. The cavity control layer may include a first portion located corresponding to one of the sub-pixels and including a reflective electrode, and a second portion including a transparent layer.

### CROSS REFERENCE TO RELATED APPLICATION

This application claims priority from and the benefit of Korean Patent Application No. 10-2025-0039586, filed on Mar. 27, 2025, which is hereby incorporated by reference for all purposes as if fully set forth herein.

### BACKGROUND

### Field

Embodiments of the invention relate generally to a display apparatus for displaying images.

### Discussion of the Background

Display apparatuses are applied to various electronic devices, such as TVs, smart phones, laptops, and tablets. To this end, much research has been conducted to develop display apparatuses that are thinner, lighter, and have lower power consumption.

Examples of the display apparatus may include a liquid crystal display apparatus (LCD), a field light-emitting display apparatus (FED), an organic light-emitting display apparatus (OLED), and the like.

Compared to other types of display apparatuses, the organic light-emitting display apparatus has many advantages, such as fast response speed, high luminous efficiency, high brightness, large viewing angle, high contrast ratio, and excellent color reproducibility. Therefore, there has been a trend to apply organic light-emitting display apparatuses to various electronic devices. For example, organic light-emitting display apparatuses are being developed as next-generation displays having large screens and presenting high-definition images.

The above information disclosed in this Background section is only for understanding of the background of the inventive concepts, and, therefore, it may contain information that does not constitute prior art.

### SUMMARY

Display apparatuses according to embodiments of the invention have a reduced number of stacks constituting a light-emitting layer of a light-emitting device in a medium-to-large-sized display panel.

Display apparatuses according to embodiments of the invention are capable of operating with reduced power consumption by reducing the number of stacks and decreasing a driving voltage at the same amount of current.

Display apparatuses according to embodiments of the invention are capable of emitting blue light without using a color filter. Furthermore, embodiments of the invention provide a display apparatus whose process can be simplified by omitting a color filter and avoiding the use of expensive equipment.

Display apparatuses according to embodiments of the invention are capable of emitting blue light whose light efficacy becomes higher by excluding the use of a color filter.

Additional features of the inventive concepts will be set forth in the description which follows, and in part will be apparent from the description, or may be learned by practice of the inventive concepts.

According to one or more embodiments of invention, a display apparatus includes a substrate including a plurality of sub-pixels; a first electrode disposed in each of the sub-pixels; a light-emitting layer disposed on the first electrode; a second electrode disposed on the light-emitting layer; and a cavity control layer disposed between the first electrode and the substrate. The cavity control layer includes a first portion located corresponding to one of the sub-pixels and including a reflective electrode, and a second portion including a transparent layer.

The first portion and the second portion of the cavity control layer may be disposed on a same plane.

The sub-pixel may include: a first sub-pixel configured to emit light of a first color; a second sub-pixel configured to emit light of a second color different from the first color; a third sub-pixel configured to emit light of a third color different from the first color and the second color; and a fourth sub-pixel configured to emit light of white color different from the first to third colors. The first portion of the cavity control layer may be disposed corresponding to the third sub-pixel.

The display apparatus may further include a first color filter disposed corresponding to the first sub-pixel and a second color filter disposed corresponding to the second sub-pixel.

The light-emitting layer may include stacks laminated in two or less layers, each stack including a hole transporting layer, an organic light-emitting layer, and an electron transporting layer.

The light-emitting layer may include: a first stack including a first common layer, a first light-emitting material layer, and a second common layer; a second stack including a third common layer, a second light-emitting material layer, a third light-emitting material layer, and a fourth common layer; and a first charge generation layer disposed between the second common layer of the first stack and the third common layer of the second stack.

Each of the first portion and the second portion of the cavity control layer may include photocatalytic transition metal oxide.

The photocatalytic transition metal oxide may include mixture molecules, the mixture modules may include metal molecules bonded to a plurality of functional groups included in photoisomerization diarylethene molecules.

The metal molecule may include aluminum (Al), silver (Ag), gold (Au), copper (Cu), titanium (Ti), germanium (Ge), or silicon (Si).

The first portion of the cavity control layer may include aggregated metal molecules of adjacent mixture molecules contained in the photocatalytic transition metal oxide, to which light is irradiated, and the second portion may include desorbed metal molecules from the mixture molecules.

The first portion may have a reflectivity in a range of substantially 40% to substantially 64% of a light incident on the first portion.

The substrate may include: a first surface and a second surface opposite to the first surface. The first electrode, the light-emitting layer, the second electrode, and the cavity control layer may be disposed in an upper side of the first surface, and the second surface of the substrate may be a light-emitting surface from which light emitted from the light-emitting layer is emitted to the outside.

The cavity control layer may have a thickness in a range of substantially 450 Å to substantially 550 Å.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a plan view of a display apparatus according to an embodiment of the invention.

FIG. 2 is a plan view showing a unit pixel according to an embodiment of the invention.

FIG. 3 is a cross-sectional view taken along line I-I′ in FIG. 2 according to an embodiment of the invention.

FIG. 4 is a cross-sectional view showing, in a magnified scale, an area “A” of FIG. 3 according to an embodiment of invention.

FIG. 5 is a cross-sectional view taken along line I-I′ in FIG. 2 according to another embodiment of the invention.

FIG. 6 is a cross-sectional view showing, in a magnified scale, an area “A” of FIG. 5 according to an embodiment of the invention.

FIG. 7, FIG. 8, FIG. 9, FIG. 10, FIG. 11, and FIG. 12 are views for explaining a cavity control layer according to another embodiment of the invention.

FIG. 13 is a graph illustrating a light-emitting spectrum of the third sub-pixel according to another embodiment of the invention . . .

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a display apparatus according to embodiments of the invention will be described with reference to the accompanying drawings.

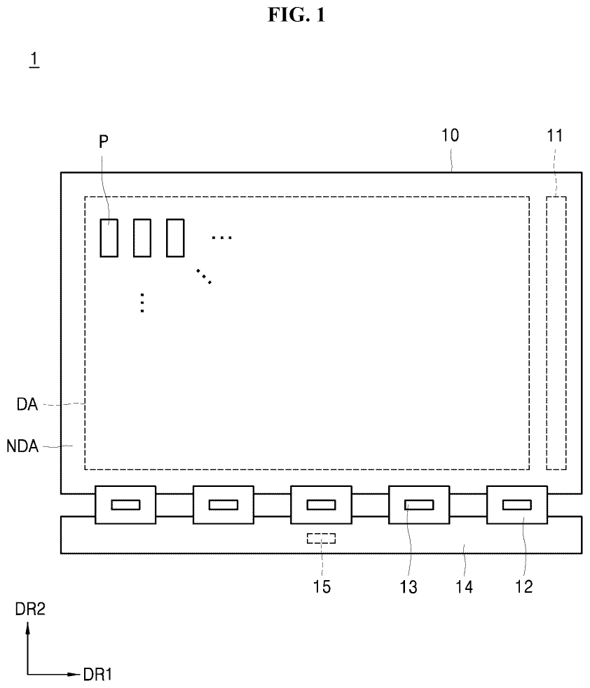

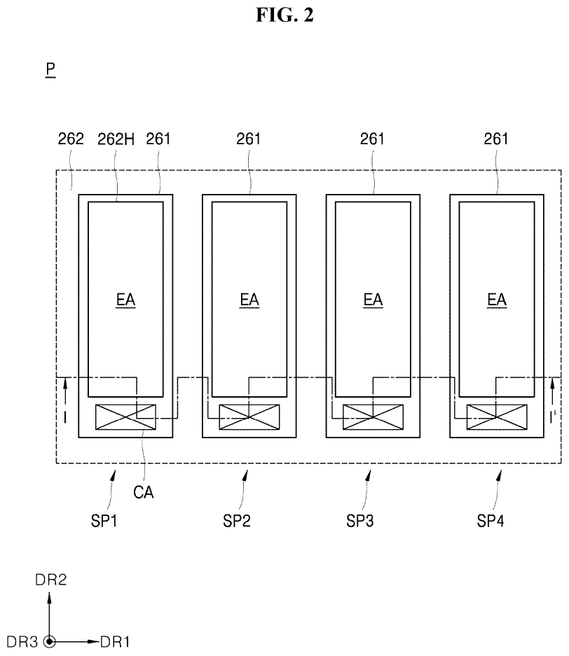

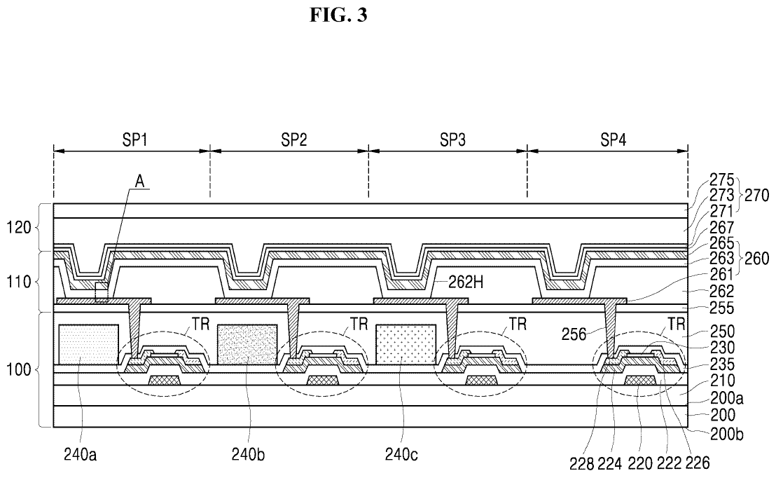

FIG. 1 is a plan view of a display apparatus according to an embodiment of the invention. FIG. 2 is a plan view showing a unit pixel according to an embodiment of the invention. FIG. 3 is a cross-sectional view taken along line I-I′ in FIG. 2 according to an embodiment of the invention. FIGS. 2 and 3 show four sub-pixels SP1, SP2, SP3, and SP4, although it is not limited thereto.

Referring to FIGS. 1 to 3, the display apparatus 1 according to embodiments of the invention may include a display panel 10, a flexible circuit board 12, an integrated circuit chip 13, a printed circuit board 14, and a control part 15.

The display panel 10 may include a display area DA and a non-display area NDA located outside the display area DA. The display area DA may be an area where an image is displayed. The non-display area NDA may be an area where no image is displayed. The non-display area NDA may be located in the peripheral area (or border area) of the display panel 10, although it is not limited thereto. For example, the remaining portion of the display area DA except a light-emitting area from which light is emitted to the outside may be referred to as the non-display area NDA.

In the display area DA a plurality of pixels P may be disposed. Through the plurality of pixels P in the display area DA, an image can be displayed. In the non-display area NDA, there may be disposed various wirings and circuits for driving the plurality of pixels P in the display area DA. For example, in the non-display area NDA, there may be disposed driving circuits including a gate driving circuit and a data driving circuit.

In the non-display area NDA, there may be disposed several driving parts 11 for driving the display area DA. For example, the driving part 11 may include, but is not limited to, a gate driving part and a data driving part. In an example, the gate driving part may be configured in a GIP (Gate driving part In Panel) manner in the non-display area NDA of one edge or opposite edges of the display area DA. The gate driving part may generate gate signals. The gate signals may be provided to pixels on the display area DA through scan lines. The data driving part may generate data signals. The data signals may be provided to pixels in the display area DA through a plurality of data wirings.

In at least one side edge of the non-display area NDA a flexible circuit board 12 and a printed circuit board 14 may be disposed. For example, a plurality of flexible circuit boards 12 may be disposed, although the embodiments are not limited thereto. On the flexible circuit board 12 an integrated circuit chip 13 may be disposed. One side of the flexible circuit board 12 may be coupled with the display panel 10, and the other side thereof may be coupled with the printed circuit board 14. The integrated circuit chip 13 may provide various signals, which have been supplied from the printed circuit board 14, to the display area DA of the display panel 10. For example, the various signals may include a high potential voltage, a low potential voltage, a scan signal, or data signals.

The printed circuit board 14 may supply signals to the integrated circuit chip 13 disposed in the flexible circuit board 12. On the printed circuit board 14, there may be disposed various components for supplying various signals to the integrated circuit chip 13. For example, on the printed circuit board 14, there may be included a control part 15. The control part 15 may include a timing control part.

Among the plurality of pixels of the display area DA, one pixel P may be constituted with a plurality of sub-pixels SP1, SP2, SP3, and SP4. The plurality of sub-pixels SP1, SP2, SP3, and SP4 disposed on the pixel P may each include an area emitting light corresponding to any one color. Among the plurality of sub-pixels SP1, SP2, SP3, and SP4, three or four or more sub-pixels which are neighboring to each other and correspond to different colors may constitute one pixel P emitting light of various colors. By the combination of the lights emitted from two or more sub-pixels SP1, SP2, SP3, and SP4 implementing one pixel P and neighboring to each other, the pixels P can display various colors, thereby emitting an image to the display area DA.

The plurality of sub-pixels SP1, SP2, SP3, and SP4 may be disposed on the display area DA to form an array. For example, the plurality of sub-pixels SP1, SP2, SP3, and SP4 may be disposed to form a matrix type array while being spaced apart from each other in a first direction DR1 of the display area DA and a second direction DR2 intersecting with the first direction DR1. The first direction DR1 may be referred to as an X-axis direction, a horizontal direction, a lateral direction, or a row direction, although it is not limited thereto. The second direction DR2 may be referred to as a Y-axis direction, a vertical direction, a longitudinal direction, or a column direction, although it is not limited thereto. The third direction DR3 may be referred to as a Z-axis direction, a thickness direction, or a depth direction, although it is not limited thereto. The arrangement order and arrangement direction of the sub-pixels SP1, SP2, SP3, and SP4 are not limited to the matrix-type array, and may be variously changed.

Referring to FIG. 2, a light-emitting area EA and a circuit area CA may be disposed corresponding to each sub-pixel SP1, SP2, SP3, and SP4. Each light-emitting area EA may be defined by a bank 262 including a bank hole 262H. The bank hole 262H may be an opening exposing the light-emitting area EA.

A plurality of first electrodes 261 may be disposed corresponding to the respective sub-pixels SP1, SP2, SP3, and SP4. The neighboring first electrodes 261 may be disposed in the respective sub-pixels SP1, SP2, SP3, and SP4 to be spaced apart from each other. A portion of the first electrode 261 uncovered due to the bank hole 262H of the bank 262 may be defined as the light-emitting area.

The light-emitting areas EA disposed in the respective sub-pixels SP1, SP2, SP3, and SP4 may emit lights of different colors. For example, the first sub-pixel SP1 may have a first light-emitting area located therein and emitting a light of a first color; the second sub-pixel SP2 may have a second light-emitting area located therein and emitting a light of a second color; the third sub-pixel SP3 may have a third light-emitting area located therein and emitting a light of a third color; and the fourth sub-pixel SP4 may have a fourth light-emitting area located therein and emitting a light of a fourth color. For example, the light of the first color may be a red light; the light of the second color may be a green light; the light of the third color may be a blue light; and the light of the fourth color may be a white light. However, the embodiments of the invention are not limited to this. Further, the arrangement order and arrangement direction of the sub-pixels SP1, SP2, SP3, and SP4 may be changed in various ways.

In the circuit area CA, circuit elements, such as a thin film transistor or a capacitor, may be disposed for driving light-emitting elements. Hereinafter, description will be made with reference to FIG. 3.

The display apparatuses may be classified into a top light-emitting type or a bottom light-emitting type according to a direction in which light emitted from a light-emitting layer is emitted. The display apparatus according to an embodiment of the invention will be described, by way of example, based on a bottom light-emitting type.

Referring to FIGS. 1 and 3, the display panel 10 may include a substrate 200, a pixel driving circuit including a plurality of thin film transistors TR mounted on the substrate 200, a light-emitting element 260, and an encapsulation part 270. One sub-pixel may include the light-emitting element 260 and a pixel driving circuit applying a driving current to the light-emitting element 260. The pixel driving circuit is disposed on the substrate 200, and the light-emitting element 260 is disposed on the pixel driving circuit. The pixel driving circuit may include the plurality of thin film transistors TR and a storage capacitor (not shown). The encapsulation part 270 may seal the pixel driving circuit and the light-emitting element 260.

For example, a portion in which the pixel driving circuit is disposed may be referred to as a driving circuit array part 100. A portion in which the light-emitting element 260 is disposed may be referred to as a light-emitting array part 110. And a portion in which the encapsulation part 270 is disposed may be referred to as a sealing part 120.

The substrate 200 may be a transparent substrate. The substrate 200 may be formed from an insulating material. The substrate 200 may include a material having transparency and flexibility. For example, the substrate 200 may include glass or a plastic film. For example, in a case where the substrate 200 is formed from a plastic film, multiple layers of an insulating material may be included. For example, the substrate 200 may include polyimide (PI).

The thin film transistor TR may include a gate electrode 220, a gate insulating layer 222, a semiconductor layer 224, a source electrode 226, and a drain electrode 228. In one example, the thin film transistor TR may be a driving transistor for driving a light-emitting element. However, the embodiments are not limited thereto. The thin film transistor TR may further include a switching transistor.

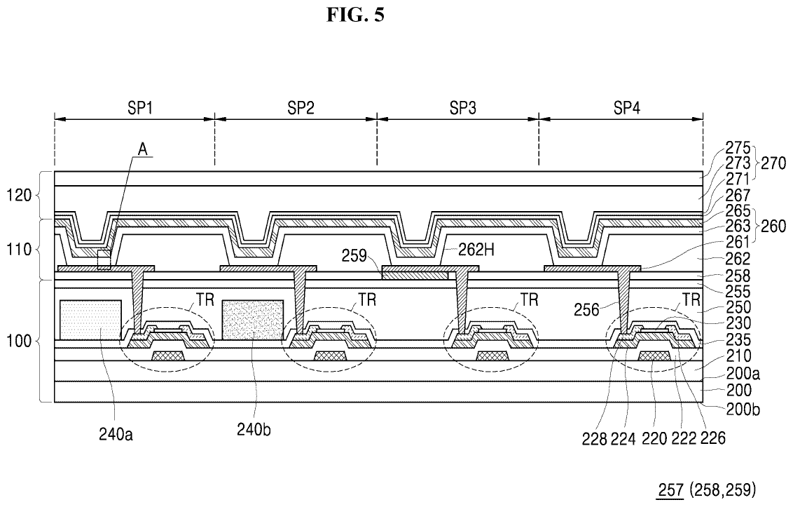

The substrate 200 may include a first surface 200a and a second surface 200b opposite to the first surface 200a. The first surface 200a of the substrate 200 may be an incidence surface on which light emitted from the light-emitting element 260 is incident. The second surface 200b of the substrate 200 may be a light-emitting surface from which light emitted from the light-emitting element 260 is emitted to the outside. In the upper side of the first surface 200a of the substrate 200, the first electrode 261, a light-emitting layer 263, a second electrode 265, and a cavity control layer 257 (See FIG. 5) may be disposed.

Between the substrate 200 and the thin film transistor TR, a buffer layer 210 may be disposed.

The buffer layer 210 may be disposed on the first surface 200a of the substrate 200. The buffer layer 210 may include a structure in which one or more insulating layers are stacked. The buffer layer 210 may reduce or prevent penetration of moisture, oxygen, or impurities through the substrate 200. Thereby, the thin film transistors TR can be protected from moisture, oxygen or impurities penetrating through the substrate 200. The buffer layer 210 may include, but is not limited to, an inorganic insulating material including silicon oxide (SiOx) or silicon nitride (SiNₓ).

The gate electrode 220 may include a metal material. For example, the gate electrode 220 may be formed from any one or an alloy of molybdenum (Mo), aluminum (Al), chromium (Cr), gold (Au), titanium (Ti), nickel (Ni), neodymium (Nd), and copper (Cu). The gate electrode 220 may be formed in a single layer or multiple layers.

On the gate electrode 220, the gate insulating layer 222 may be disposed. The gate insulating layer 222 may be disposed to cover the gate electrode 220. In one example, the gate insulating layer 222 may be disposed on the entire surface of the substrate 200. The gate insulating layer 222 may include an inorganic insulating material. In one example, the gate insulating layer 222 may include silicon oxide (SiOx) or silicon nitride (SiNₓ).

On the gate insulating layer 222, the semiconductor layer 224 may be disposed. The semiconductor layer 224 may include a semiconductor material. The semiconductor layer 224 may include a silicon-based semiconductor material. For example, the semiconductor layer 224 may be formed from polysilicon. In another example, the semiconductor layer 224 may include amorphous silicon or an oxide semiconductor material. The semiconductor layer 224 may be insulated from the gate electrode 220 by the gate insulating layer 222. The semiconductor layer 224 may include a channel area, a source area, and a drain area. The channel area may be an area overlapping with the gate electrode 220 in an up and down direction. The source area and the drain area may be located on opposite sides of the channel area.

On the semiconductor layer 224, the source electrode 226 and the drain electrode 228 may be disposed. The source electrode 226 and the drain electrode 228 may be disposed to be spaced apart from each other. For example, the source electrode 226 may overlap, in the up and down direction, with a source area disposed in one side of the semiconductor layer 224. The drain electrode 228 may overlap, in the up and down direction, with a drain area disposed in the other side of the semiconductor layer 224.

Between the source electrode 226 and the drain electrode 228, an etch stop layer 230 may be disposed. The etch stop layer 230 may prevent that the semiconductor layer 224 between the source electrode 226 and the drain electrode 228 spaced apart from each other is damaged in an etching process. The etch stop layer 230 may include, but is not limited to, an inorganic insulating material.

The source electrode 226 and the drain electrode 228 may each be formed in, but are not limited to, multiple layers formed from any one or an alloy of molybdenum (Mo), aluminum (Al), chromium (Cr), gold (Au), titanium (Ti), nickel (Ni), neodymium (Nd), and copper (Cu). For example, the source electrode 226 and the drain electrode 228 may include a configuration in which second metal layers are disposed on the upper surface and the lower surface of a first metal layer, respectively, with the first metal layer interposed therebetween. For example, the first metal layer may include aluminum (Al), and the second metal layer may include titanium (Ti).

The thin film transistor TR according to an embodiment of the invention may have a bottom gate structure in which the gate electrode 220, the semiconductor layer 224, and the source/drain electrodes 226, 228 are sequentially stacked on the buffer layer 210.

On the source electrode 226, the etch stop layer 230, and the drain electrode 228 of the thin film transistor TR, a first passivation layer 235 may be disposed. The first passivation layer 235 may protect the thin film transistor TR. The first passivation layer 235 may include an inorganic insulating material. For example, the first passivation layer 235 may include silicon nitride (SiNₓ).

On the upper side of the first passivation layer 235, color filters 240a, 240b, 240c may be disposed. The color filters 240a, 240b, 240c may be disposed in the sub-pixels SP1, SP2, and SP3, respectively, except for the fourth sub-pixel SP4. For example, the color filters 240a, 240b, 240c may each be disposed at positions corresponding to the light-emitting areas of the first sub-pixel SP1, the second sub-pixel SP2, and the third sub-pixel SP3. Each color filter 240a, 240b, 240c may be formed to emit a light of red, green, or blue. In the fourth sub-pixel SP4, which emits a light of white, no color filter is disposed.

On the first passivation layer 235 and the color filters 240a, 240b, 240c, a planarization layer 250 may be disposed. The planarization layer 250 may planarize a step difference generated by the underlying circuit elements including the thin film transistors TR. The planarization layer 250 may include a transparent organic insulating material. For example, the planarization layer 250 may include, but is not limited to, acrylic resin, epoxy resin, phenolic resin, polyamide resin, or polyimide resin. The planarization layer 250 may be formed in a single layer, or in double or multiple layers. The planarization layer 250 may also be referred to as an overcoating layer.

The planarization layer 250 may be disposed to cover the color filters 240a, 240b, 240c.

On the planarization layer 250 a second passivation layer 255 may be disposed. The second passivation layer 255 may include an inorganic insulating material. For example, the second passivation layer 255 may include silicon nitride (SiNₓ).

In the upper side of the second passivation layer 255, the light-emitting element 260 may be disposed. The light-emitting element 260 may include the first electrode 261, the light-emitting layer 263, and the second electrode 265. The light-emitting element 260 may be electrically connected with the pixel driving circuit through the first electrode 261. For example, a portion of the first electrode 261 may be formed as a pixel contact electrode 256 connected to the drain electrode 228 by penetrating the second passivation layer 255, the planarization layer 250 and the first passivation layer 235. Thereby, the first electrode 261 may be electrically connected to the thin film transistor TR through the pixel contact electrode 256.

The first electrode 261 may include a transparent conductive film. For example, the first electrode 261 may include indium-tin-oxide (ITO) or indium-zinc-oxide (IZO). The first electrode 261 may also be referred to as an anode electrode or a pixel electrode.

On the first electrode 261 a bank 262 may be disposed. The bank 262 may be disposed so as to cover the edges of the first electrode 261. A portion of the bank 262 may be extended to the second passivation layer 255. The bank 262 may include a bank hole 262H exposing a portion of the first electrode 261. The upper surface of the first electrode 261 exposed by the bank hole 262H of the bank 262 may become a light-emitting area. In one example, the bank 262 may include a black material, a light-shielding material, or a light-absorbing material. The bank 262 may be formed from an organic insulating material. The bank 262 may include, for example, photosensitive polyimide, photoacrylic, or benzocyclobutene (BCB).

On the first electrode 261 a light-emitting layer 263 may be disposed. The light-emitting layer 263 may include an organic light-emitting material. The organic light-emitting material may be formed from a phosphorescence material or a fluorescence material. The organic light-emitting material may emit light of a specific color depending on the material when current is applied. For example, the organic light-emitting material may emit light of one color among red, green, and blue. However, is the embodiments are not limited to these colors.

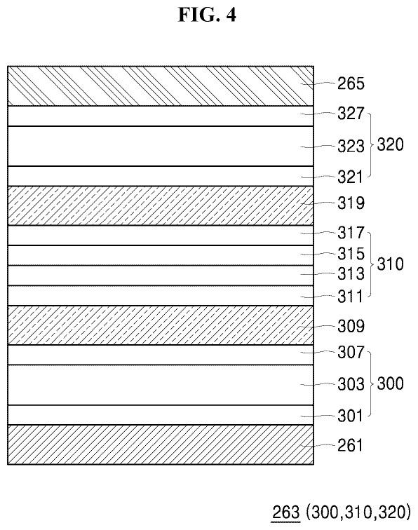

The light-emitting layer 263 may include a multi-stack structure in which stacks are laminated in at least three or more layers, each stack including a hole transporting layer (HTL), an organic light-emitting layer (EML), and an electron transporting layer (ETL). Description of this will be made below with reference to FIG. 4.

Among the components of the light-emitting layer 263, the organic light-emitting layer (EML) may be disposed only in pixels of the display area DA, although the embodiments are not limited thereto.

On the light-emitting layer 263, the second electrode 265 may be disposed. The second electrode 265 may be commonly connected with the light-emitting layer 263 formed in all pixels. Therefore, the second electrode 265 may also be referred to as a cathode electrode or a common electrode. The second electrode 265 may include a semi-transparent conductive material. For example, the second electrode 265 may be formed from a metal material having a high reflectivity, such as magnesium (Mg), silver (Ag), or an alloy (Ag—Mg) of silver (Ag) and magnesium (Mg).

On the second electrode 265, the capping layer 267 may be disposed. The capping layer 267 can prevent that the light-emitting layer 263 is damaged by contamination or moisture penetration from the outside.

On the light-emitting element 260 the encapsulation part 270 may be disposed. The encapsulation part 270 may protect the light-emitting element 260 from external oxygen or moisture. The encapsulation part 270 may cover the display area DA. The encapsulation part 270 may extend to the non-display area NDA outside the display area DA.

In the encapsulation part 270, a multilayer structure may be disposed, which includes a first encapsulation layer 271, a second encapsulation layer 273, and a third encapsulation layer 275. The second encapsulation layer 273 may be configured to be disposed between the first encapsulation layer 271 and the third encapsulation layer 275.

The first encapsulation layer 271 may be disposed on the capping layer 267. The second encapsulation layer 273 may be disposed on the first encapsulation layer 271. The second encapsulation layer 273 may cover the first encapsulation layer 271, and may have a sufficient thickness to have a flat surface. The second encapsulation layer 273 may prevent foreign substances from penetrating into the light-emitting element 260. On the second encapsulation layer 273, the third encapsulation layer 275 may be disposed. The first encapsulation layer 271 and the third encapsulation layer 275 may extend to the non-display area.

The first encapsulation layer 271 and the third encapsulation layer 275 may include an inorganic insulating material, and the second encapsulation layer 273 may include an organic insulating material. For example, each of the first encapsulation layer 271 and the third encapsulation layer 275 may include at least one material among silicon nitride (SiNₓ), silicon oxide (SiOx), and silicon oxynitride (SiON). The second encapsulation layer 273 may include at least one material among epoxy, polyimide, polyethylene, and acrylate.

FIG. 4 is a cross-sectional view showing, in a magnified scale, an area “A” of FIG. 3 according to an embodiment of the invention.

Referring to FIGS. 3 and 4, the light-emitting layer 263 may be disposed between the first electrode 261 and the second electrode 265. The light-emitting layer 263 may include a stack including at least a hole transporting layer (HTL), an emission material layer (EML), and an electron transporting layer (ETL). The light-emitting layer 263 may include a multi-stack structure in which at least three or more stacks are laminated. In one example, one stack may further include a hole blocking layer (HBL), a hole injecting layer (HIL), an electron blocking layer (EBL), and an electron injecting layer (EIL).

For example, the light-emitting layer 263 may include a structure in which a first stack 300, a second stack 310, and a third stack 320 are laminated. For example, the first stack 300 may include a first common layer 301, a first emission material layer 303, and a second common layer 307. The first common layer 301 may be a hole transporting layer or a hole injection layer. The first common layer 301 may deliver holes to the first emission material layer 303. The second common layer 307 may be an electron transport layer. The second common layer 307 may deliver electrons to the first emission material layer 303. The first emission material layer 303 may be a blue emission material layer. The first emission material layer 303 may include a fluorescence material.

The second stack 310 may include a third common layer 311, a second emission material layer 313, a third emission material layer 315, and a fourth common layer 317. The third common layer 311 may be a hole transporting layer. The third common layer 311 may deliver holes to the second emission material layer 313 and the third emission material layer 315. The fourth common layer 317 may be an electron transport layer. The fourth common layer 317 may deliver electrons to the second emission material layer 313 and the third emission material layer 315. The second emission material layer 313 may be a red emission material layer, and the third emission material layer 315 may be a green emission material layer. In one example, the second emission material layer 313 and the third emission material layer 315 may include a phosphorescence material.

The third stack 320 may include a fifth common layer 321, a fourth emission material layer 323, and a sixth common layer 327. The fifth common layer 321 may be a hole transporting layer, and may deliver holes to the fourth emission material layer 323. The sixth common layer 327 may be an electron transport layer and/or an electron injecting layer. The sixth common layer 327 may transport or deliver electrons injected from the second electrode 265. The fourth emission material layer 323 may be a blue emission material layer. The fourth emission material layer 323 may include a fluorescence material.

Between the second common layer 307 of the first stack 300 and the third common layer 311 of the second stack 310, a first charge generation layer (CGL) 309 may be disposed. For example, the first charge generation layer 309 may include an n-type charge generation layer and a p-type charge generation layer. The third common layer 311 may deliver holes generated from the first charge generation layer 309 to the second emission material layer 313 and the third emission material layer 315 of the second stack 310.

Between the fourth common layer 317 of the second stack 310 and the fifth common layer 321 of the third stack 320, a second charge generation layer 319 may be disposed. The second charge generation layer 319 may include an n-type charge generation layer and a p-type charge generation layer. The fifth common layer 321 may deliver holes of the second charge generation layer 319 to the fourth emission material layer 323. In addition, the sixth common layer 327 may deliver electrons injected from the second electrode 265 to the fourth emission material layer 323.

By including the first electrode 261, the light-emitting layer 263, and the second electrode 265, the light-emitting element 260 (see FIG. 3) may be constructed. The light-emitting element 260 may emit white light through the combination of colors emitted from the light-emitting layer 263.

The white light emitted from the light-emitting element 260 may be emitted as a light of different color through the color filter 240. For example, referring to FIG. 3, at positions corresponding to the light-emitting areas of respective sub-pixels SP1, SP2, SP3, the color filter 240a, 240b, 240c may be disposed. The color filter 240a, 240b, 240c may include a first color filter 240a, a second color filter 240b, and a third color filter 240c. The first color filter 240a may be disposed corresponding to the first sub-pixel SP1. The second color filter 240b may be disposed corresponding to the second sub-pixel SP2. The third color filter 240c may be disposed corresponding to the third sub-pixel SP3.

The color filters 240a, 240b, 240c can selectively transmit light in a wavelength range corresponding to each sub-pixel SP1, SP2, SP3 from white light emitted from the light-emitting layer 263. Thereby, lights of different colors can be emitted to the outside from the respective sub-pixels SP1, SP2, SP3.

For example, white light emitted from the light-emitting element 260 of the first sub-pixel SP1 may pass through the first color filter 240a to be emitted as a red light. White light emitted from the light-emitting element 260 of the second sub-pixel SP2 may pass through the second color filter 240b to be emitted as a green light. White light emitted from the light-emitting element 260 of the third sub-pixel SP3 may pass through the third color filter 240c to be emitted as a blue light. Since no color filter is disposed in the fourth sub-pixel SP4, white light emitted from the light-emitting element 260 can be emitted.

Meanwhile, blue light may have a greater amount of light loss by the color filter, resulting in reduced light efficiency compared to lights of the other colors. For example, the blue light may have a light efficacy value of 3.4 (Cd/A). Also, it may have a color reproduction range of 97.4%. For example, the second emission material layer 313 and the third emission material layer 315 may include phosphorescence material. The first emission material layer 303 and the fourth emission material layer 323 may include fluorescence material. Light generated through phosphorescence material can be emitted at 100% light efficiency. However, light generated through fluorescence material has lower light efficiency than that of the light generated through phosphorescence material. For example, light generated through fluorescence material may be emitted at a light efficiency of 25%. Thereby, the light efficacy of blue light is less than those of red and green lights.

Moreover, the number of pixels disposed in medium-to-large-sized display panels used in televisions or the like is greater than the number of pixels disposed in small-sized display panels used in mobile devices or the like. As a result, the number of light-emitting layer stack structures disposed in each pixel also increases. As the number of light-emitting layer stack structures increases, the driving voltage for driving the light-emitting layer may increase. For medium-to-large-sized display panels, power consumption may increase as the driving voltage increases at the same current.

Because of this, in another embodiment of the invention, a display apparatus may be constructed, which is capable of emitting blue light without using a color filter, by controlling, through a microcavity effect, light emitted from a light-emitting element, which has a specific wavelength. Further, in another embodiment of the invention, a display apparatus may be constructed, which is capable of reducing power consumption in a medium-to-large-sized display panel by decreasing a driving voltage at the same amount of current.

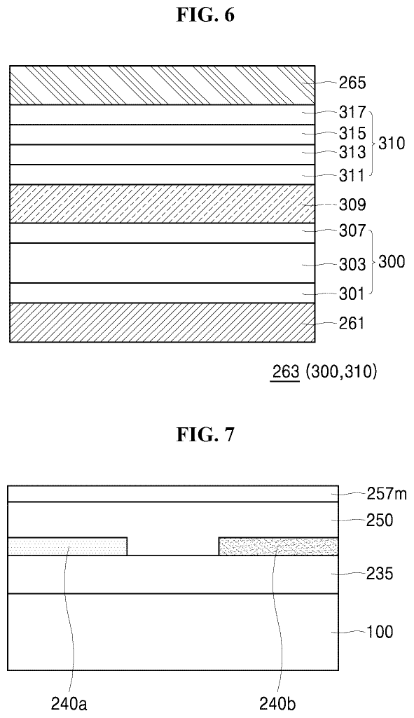

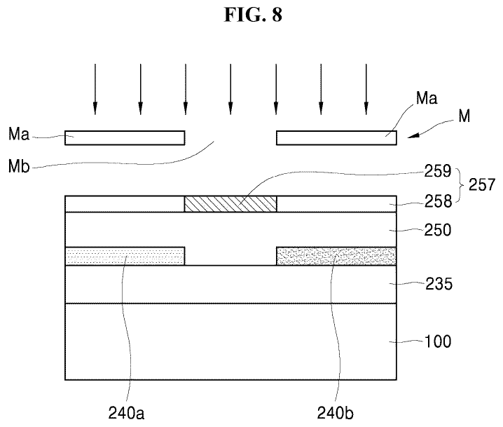

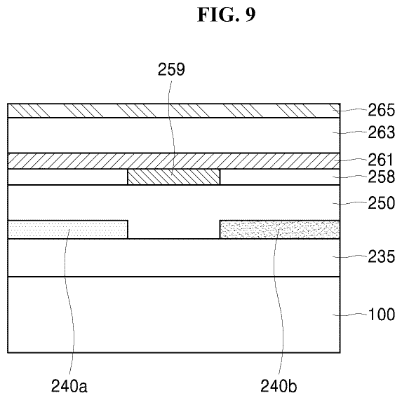

FIG. 5 is a cross-sectional view taken along line I-I′ in FIG. 2 according to another embodiment of the present invention FIG. 6 is a cross-sectional view showing, in a magnified scale, an area “A” of FIG. 5 according to an embodiment of the invention. In FIGS. 5 and 6, the same reference numerals are given to the same components as those described in FIGS. 3 and 4, and the description thereof will be simplified or omitted.

Referring to FIGS. 5 and 6, the substrate 200 may be prepared, which includes the driving circuit array part 100, the light-emitting array part 110, and the sealing part 120. The driving circuit array part 100 may include a pixel driving circuit including various signal wires, a plurality of thin film transistors TR, a storage capacitor, and the like. The light-emitting array part 110 may include the light-emitting element 260. The sealing part 120 may include the encapsulation part 270.

The substrate 200 may be formed from a transparent material. For example, the substrate 200 may include glass or a plastic film. The substrate 200 may include the first surface 200a which is an incidence surface, and the second surface 200b which is a light-emitting surface. To the first surface 200a, the light emitted from the light-emitting element 260 may be incident. From the second surface 200b, the light emitted from the light-emitting element 260 may be emitted to the outside. In one example, the first surface 200a may be referred to as the “front face”, and the second surface 200b may be referred to as the “rear face”.

On the first surface 200a of the substrate 200, the thin film transistor TR may be disposed. The thin film transistor TR may include a gate electrode 220, a gate insulating layer 222, a semiconductor layer 224, a source electrode 226, and a drain electrode 228. In one example, the thin film transistor TR may be a driving transistor for driving a light-emitting element. However, the embodiments are not limited thereto. The thin film transistor TR may further include a switching transistor.

Between the substrate 200 and the gate electrode 220 of the thin film transistor TR, the buffer layer 210 may be disposed. The buffer layer 210 may include a structure in which one or more insulating layers are stacked. The buffer layer 210 may include an inorganic insulating material. For example, the buffer layer 210 may include silicon oxide (SiOx) or silicon nitride (SiNₓ).

The gate insulating layer 222 can be disposed between the gate electrode 220 and the semiconductor layer 224. The etch stop layer 230 may be disposed between the source electrode 226 and the drain electrode 228 to cover a portion of the surface of the semiconductor layer 224.

The semiconductor layer 224 may include a semiconductor material. The semiconductor layer 224 may include a silicon-based semiconductor material. For example, the semiconductor layer 224 may be formed from polysilicon. In another example, the semiconductor layer 224 may include amorphous silicon or an oxide semiconductor material.

The source electrode 226 and the drain electrode 228 may be disposed on the semiconductor layer 224 to be spaced apart from each other. The source electrode 226 and the drain electrode 228 may each be formed in, but are not limited to, multiple layers formed from any one or an alloy of molybdenum (Mo), aluminum (Al), chromium (Cr), gold (Au), titanium (Ti), nickel (Ni), neodymium (Nd), and copper (Cu). For example, the source electrode 226 and the drain electrode 228 may include a configuration in which second metal layers are disposed on the upper surface and the lower surface of a first metal layer, respectively, with the first metal layer interposed therebetween. For example, the first metal layer may include aluminum (Al), and the second metal layer may include titanium (Ti).

The thin film transistor TR according to another embodiment of the invention may have a bottom gate structure in which the gate electrode 220 is disposed at a location close to the first surface 200a of the substrate 200 with the gate insulating layer 222, the semiconductor layer 224, the source electrode 226, and the drain electrode 228 disposed thereon.

On the thin film transistor TR, the first passivation layer 235 may be disposed. The first passivation layer 235 may include an inorganic insulating material. For example, the first passivation layer 235 may include silicon nitride (SiNₓ).

On the first passivation layer 235, a plurality of color filters 240a, 240b may be disposed. The color filters 240a, 240b may be disposed in some sub-pixels SP1, SP2 of the sub-pixels SP1, SP2, SP3, and SP4. The color filters 240a, 240b may include the first color filter 240a and the second color filter 240b. The first color filter 240a and the second color filter 240b may selectively transmit lights of different color wavelength ranges from the light emitted from the light-emitting element 260, allowing the lights to be emitted toward the second surface 200b of the substrate 200, which is the light-emitting surface. For example, the first color filter 240a may selectively transmit light in the red wavelength range. The second color filter 240b may selectively transmit light in the green wavelength range.

The first color filter 240a and the second color filter 240b may be disposed at locations corresponding to the light-emitting areas of the first sub-pixel SP1 and the second sub-pixel SP2, respectively. In the display apparatus according to another embodiment of the invention, the third sub-pixel SP3 and the fourth sub-pixel SP4 do not have any color filters disposed therein.

On the first passivation layer 235, the first color filter 240a, and the second color filter 240b, the planarization layer 250 may be disposed. The planarization layer 250 may planarize a step difference generated by the underlying circuit elements. The planarization layer 250 may include a transparent organic insulating material. For example, the planarization layer 250 may include, but is not limited to, acrylic resin, epoxy resin, phenolic resin, polyamide resin, or polyimide resin. The planarization layer 250 may be formed in a single layer, or in double or multiple layers. The planarization layer 250 may also be referred to as an “overcoating” layer. The planarization layer 250 may cover the first color filter 240a and the second color filter 240b.

On the flat surface of the planarization layer 250, the second passivation layer 255 may be disposed. The second passivation layer 255 may include an inorganic insulating material. For example, the second passivation layer 255 may include silicon nitride (SiNₓ).

On the second passivation layer 255, a cavity control layer 257 may be disposed. The cavity control layer 257 may include a first portion 259 and a second portion 258. Each of the first portion 259 and the second portion 258 of the cavity control layer 257 may include a photocatalytic transition metal oxide. The photocatalytic transition metal oxide may include mixture molecules of a metal molecule and a photoisomerization diarylethene molecule including functional groups. The first portion 259 of the cavity control layer 257 may be an active portion activated by irradiating light onto the photocatalytic transition metal oxide. The second portion 258 of the cavity control layer 257 may be a portion of the photocatalytic transition metal oxide, which is inactivated because it has not been exposed to light. For example, the first portion 259 of the cavity control layer 257 may be formed by metal nucleation generated as metal molecules of adjacent mixture molecules among the mixture molecules contained in the photocatalytic transition metal oxide are aggregated. Thereby, the first portion 259 can be a semi-transparent reflective electrode having reflectivity. In addition, the second portion 258 of the cavity control layer 257 may be formed by the metal molecules being desorbed from the mixture molecules included in the photocatalytic transition metal oxide and being released to the outside. Thereby, the second portion 258 may be a transparent layer through which light is transmitted without being reflected. An explanation of this will be given later in FIG. 10. For example, the first portion 259 of the cavity control layer 257 may be disposed corresponding to one sub-pixel of the plurality of sub-pixels SP1, SP2, SP3, and SP4. For example, the first portion 259 of the cavity control layer 257 may be disposed at a location corresponding to the light-emitting area of the third sub-pixel SP3. The second portion 258 of the cavity control layer 257 may be disposed in the remaining area except for the area in which the first portion 259 is disposed. The cavity control layer 257 may have a thickness of 450 Å to 550 Å. For example, the first portion 259 and the second portion 258 of the cavity control layer 257 may have the same thickness. For example, the first portion 259 and the second portion 258 of the cavity control layer 257 may be located on the same plane.

On the upper side of the cavity control layer 257, the light-emitting element 260 may be disposed. The light-emitting element 260 may include the first electrode 261, the light-emitting layer 263, and the second electrode 265. The light-emitting element 260 may be electrically connected to the thin film transistor TR through the first electrode 261 and the pixel contact electrode 256.

The first electrode 261 may include a transparent conductive film. For example, the first electrode 261 may include indium-tin-oxide (ITO) or indium-zinc-oxide (IZO). In the display apparatus according to another embodiment of the invention, light may be emitted to the outside in a bottom light-emitting type. Therefore, the first electrode 261 may be formed of a transparent conductive film to emit light, which has been emitted from the light-emitting element 260, toward the second surface 200b of the substrate 200. The first electrode 261 may also be referred to as an “anode electrode” or a “pixel electrode”.

On the first electrode 261, the bank 262 may be disposed, which has the bank hole 262H to define the light-emitting area. The bank 262 may be disposed so as to cover the edges of the first electrode 261. The upper surface of the first electrode 261 exposed through the bank hole 262H may be a light-emitting area. The bank 262 may be formed from an organic insulating material. In one example, the bank 262 may include a black material, a light-shielding material, or a light-absorbing material.

On the first electrode 261 a light-emitting layer 263 may be disposed. The light-emitting layer 263 may include an organic light-emitting material. The organic light-emitting material may emit light of one color among red, green, and blue.

The light-emitting layer 263 may include a multi-stack structure in which stacks are laminated in two or less layers, each stack including a hole transporting layer (HTL), an organic light-emitting layer (EML), and an electron transporting layer (ETL). For example, the light-emitting layer 263 may include a multi-stack structure in which two stacks are laminated. The organic light-emitting layer (EML) may be disposed only in pixels of the display area DA, although it is not limited thereto.

Referring to FIGS. 5 and 6 together, the light-emitting layer 263 may be disposed between the first electrode 261 and the second electrode 265. The light-emitting layer 263 may include a stack including a hole transporting layer (HTL), an emission material layer (EML), and an electron transporting layer (ETL). The light-emitting layer 263 according to another embodiment of the invention may include a multi-stack structure in which two stacks are laminated. In one example, one stack may further include a hole blocking layer (HBL), a hole injecting layer (HIL), an electron blocking layer (EBL), and an electron injecting layer (EIL).

For example, the light-emitting layer 263 may include a structure in which a first stack 300 and a second stack 310 are laminated. For example, the first stack 300 may include a first common layer 301, a first emission material layer 303, and a second common layer 307. The first common layer 301 may be a hole transporting layer or a hole injection layer. The first emission material layer 303 may be a blue emission material layer. The first emission material layer 303 may include a fluorescence material.

The second stack 310 may include a third common layer 311, a second emission material layer 313, a third emission material layer 315, and a fourth common layer 317. The third common layer 311 may be a hole transporting layer. The fourth common layer 317 may be an electron transport layer. The fourth common layer 317 may deliver electrons to the second emission material layer 313 and the third emission material layer 315. The second emission material layer 313 may be a red emission material layer, and the third emission material layer 315 may be a green emission material layer. In one example, the second emission material layer 313 and the third emission material layer 315 may include a phosphorescence material.

Between the second common layer 307 of the first stack 300 and the third common layer 311 of the second stack 310, a first charge generation layer 309 may be disposed. The first charge generation layer 309 may include an n-type charge generation layer and a p-type charge generation layer.

The third common layer 311 may deliver holes of the first charge generation layer 309 to the second stack 310. Additionally, the fourth common layer 317 may deliver electrons injected from the second electrode 265 to the third emission material layer 315.

The first electrode 261 may be disposed on the lower side of the first common layer 301 of the first stack 300, and the second electrode 265 may be disposed on the fourth common layer 317 of the second stack 310.

The light-emitting element 260 may be constructed by including the first electrode 261, the light-emitting layer 263, and the second electrode 265. The light-emitting element 260 may emit white light through the combination of colors emitted from the light-emitting layer 263.

Referring back to FIG. 5, the second electrode 265 may be disposed on the light-emitting layer 263. The second electrode 265 may be commonly connected with the light-emitting layer 263 formed in all pixels. The second electrode 265 may also be referred to as a “cathode electrode” or a “common electrode”. The second electrode 265 may include a semi-transparent conductive material. For example, the second electrode 265 may be formed from a metal material having a high reflectivity, such as magnesium (Mg), silver (Ag), or an alloy (Ag—Mg) of silver (Ag) and magnesium (Mg).

In the third sub-pixel SP3, a micro-cavity effect may be obtained between the second electrode 265 and the first electrode 261 disposed on the upper side of the first portion 259 of the cavity control layer 257. Thereby, light of a color different from that of the first sub-pixel SP1 and the second sub-pixel SP2 can be emitted from the third sub-pixel SP3. For example, blue light may be emitted from the third sub-pixel SP3.

On the second electrode 265, the capping layer 267 may be disposed. On the capping layer 267, the encapsulation part 270 may be disposed. The encapsulation part 270 may include the first encapsulation layer 271, the third encapsulation layer 275, and the second encapsulation layer 273 disposed between the first encapsulation layer 271 and the third encapsulation layer 275. The first encapsulation layer 271 and the third encapsulation layer 275 may include an inorganic insulating material. The second encapsulation layer 273 may include an organic insulating material.

On the other hand, when blue light is emitted through the color filter, the amount of light lost by the color filter is great, so the light efficacy was reduced compared to those of other colors. For example, the blue light may have a light efficacy value of 3.4 (Cd/A). Also, it may have a color reproduction range of 97.4%. In contrast, in the display apparatus according to another embodiment of the invention, the first portion 259 of the cavity control layer 257 may function as a semi-transparent reflective film. Thereby, blue light can be emitted from the third sub-pixel SP3 due to the micro-cavity effect. In this case, the blue light may have a light efficiency value of 6.44 (Cd/A). Thus, the light efficiency value of blue light emitted when applying the first portion 259 of the cavity control layer 257 may be twice the light efficiency value of blue light emitted through the color filter. Accordingly, the light efficiency of the light-emitting element can be improved.

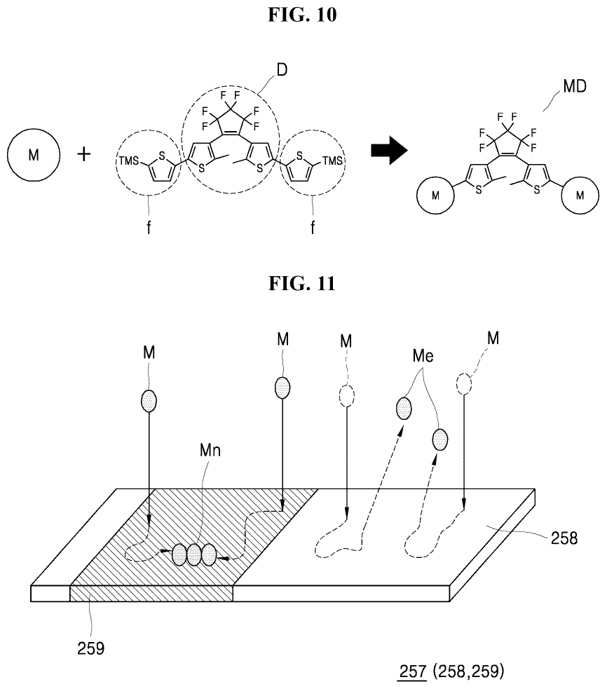

FIGS. 7 to 12 are views for explaining a cavity control layer according to another embodiment of the invention. FIGS. 7 to 9 illustrate a method of manufacturing a display apparatus including a cavity control layer according to another embodiment of the invention. FIG. 10 is a diagram for explaining a photocatalytic metal material. FIG. 11 is a diagram for explaining a process of forming an active portion of a cavity control layer using a photocatalytic metal material. FIG. 12 is a table showing reflectivities at an active portion of the cavity control layer according to exposure amounts. In FIGS. 7 to 9, the same reference symbols will be given to the same components as those described with reference to FIGS. 3 and 4, and the description thereof will be simplified or omitted.

Referring to FIG. 7, on the driving circuit array part 100, the first passivation layer 235 may be disposed. On the first passivation layer 235, the first color filter 240a and the second color filter 240a may be disposed to be spaced apart from each other. The first color filter 240a may selectively transmit light in the red wavelength range, and the second color filter 240b may selectively transmit light in the green wavelength range. In one example, the first color filter 240a may be located corresponding to the first sub-pixel, and the second color filter 240b may be located corresponding to the second sub-pixel. At a position corresponding to the third sub-pixel, no color filter is disposed. The first color filter 240a and the second color filter 240b may be covered with a planarization layer 250.

On the planarization layer 250 a cavity control material layer 257m may be formed. The cavity control material layer 257m may be disposed across the plurality of sub-pixels. For example, the cavity control material layer 257m may be disposed on the first sub-pixel SP1, the second sub-pixel SP2, the third sub-pixel SP3, and the fourth sub-pixel SP4 of FIG. 5. The cavity control material layer 257m may include a photocatalytic transition metal oxide. The cavity control material layer 257m may be formed to have a thickness of 450 Å to 550 Å, although the embodiments of the invention are not limited thereto.

The cavity control material layer 257m formed on the planarization layer 250 may be in an inactive state. The cavity control material layer 257m, which is in an inactive state, may be a transparent layer through which light is transmitted.

The photocatalytic transition metal oxide may be a transition metal-based oxide in which a chemical reaction is promoted when ultraviolet rays are irradiated thereon. For example, the photocatalytic transition metal oxide may include mixture molecules MD of a metal molecule M and a photoisomerization diarylethene molecule D containing functional groups f, as shown in FIG. 10. The photoisomerization diarylethene molecule is a molecule whose structure can be changed using light, and when it absorbs ultraviolet light, its chemical structure can be changed and its properties can be changed. The metal molecule M may include a metal material having reflectivity. For example, the metal molecule M may include aluminum (Al), silver (Ag), gold (Au), copper (Cu), titanium (Ti), germanium (Ge), or silicon (Si).

The metal molecule M may be bonded to the functional group f of the photoisomerization diarylethene molecule D to form a mixture molecule.

Referring to FIG. 8, on the cavity control material layer 257m, a mask Mis disposed. The mask M may include a plurality of pattern portions Ma and an opening Mb. The pattern portions Ma may each be located corresponding to the first color filter 240a and the second color filter 240b. For example, the pattern portions Ma may each be located corresponding to the first sub-pixel, the second sub-pixel, and the fourth sub-pixel. The opening Mb may be located corresponding to an area in which no color filter is disposed. For example, an area in which no color filter is disposed may be located corresponding to the third sub-pixel.

Next, as shown by arrows in FIG. 8, a photolithography process is performed using the mask M. Through the photolithography process, light may be irradiated onto a portion of the cavity control material layer 257m (FIG. 7) exposed through the opening Mb. In the progress of the photolithography process, the light source may employ I-line which irradiates ultraviolet rays having a wavelength of 365 nm. The resolution of the photolithography process using the I-line may be equal to or greater than 0.35 micrometers μm. The energy of the light source in the photolithography process may include 600 Mw/cm². The irradiation may be performed at an exposure amount in the range of 100 mJ to 180 mJ.

Then, the cavity control material layer 257m may become the cavity control layer 257 divided into the first portion 259 having been irradiated with the light and the second portion 258 having not been irradiated with the light. For example, the first portion 259 may be an active portion, and the second portion 258 may be an inactive portion. The first portion 259 of the cavity control layer 257, to which the light has been irradiated, can be changed into a metal component having reflectivity through an activation action by the light. Thereby, the first portion 259 may be a semi-transparent reflective film. Additionally, the second portion 258 of the cavity control layer 257, which has not been irradiated with the light because it has been blocked by the pattern portions Ma of the mask M, may remain a transparent layer because it has not undergone the activation action by the light.

For example, referring to FIGS. 10 and 11, in the first portion 259 of the cavity control material layer 257m (see FIG. 7) which has been irradiated with the light, metal nucleation Mn can be generated as metal molecules M of adjacent mixture molecules MD among the mixture molecules MD of FIG. 10 are aggregated. Thereby, the first portion 259 may be a semi-transparent reflective film. Besides, in the second portion 258 of the cavity control material layer 257m which has not been irradiated by the light, the metal molecules Me can be desorbed from the mixture molecules MD, and be released to the outside. Thereby, the second portion 258 may be a transparent layer.

The first portion 259 of the cavity control layer 257, to which the light has been irradiated, can be changed into a metal component having reflectivity through an activation action by the light. Thereby, the first portion 259 may be a semi-transparent reflective film. The reflectivity of the first portion 259 may vary according to the exposure amount irradiated to the first portion 259.

Referring to FIG. 12, when the exposure amount for the first portion 259 of the cavity control layer 257 is increased from 100 mJ to 180 mJ, the reflectivity may be changed from 64% to 40% of the total light incident on the first portion. If the reflectivity is less than 40%, the microcavity effect may be declined. Because of this, the reflectivity is equal to or greater than 40% in the embodiments of the invention. For example, the reflectivity of the first portion 259 of the cavity control layer 257 may be in the range of 40% to 64% of the light incident on the first portion 259. Therefore, the exposure amount for forming the first portion 259 of the cavity control layer 257 may be in the range of 100 mJ to 180 mJ. Here, metal molecules of the cavity control material layer 257m may be aluminum (Al).

Next, referring to FIG. 9, on the cavity control layer 257, a light-emitting element may be formed, which includes the first electrode 261, the light-emitting layer 263, and the second electrode 265.

On the other hand, instead of introducing the cavity control layer 257, a method of depositing a reflective metal layer on the second passivation layer 255 and then performing an etching process to form a reflective metal electrode may be considered. However, there may occur a problem in that the surface of the reflective metal layer is unevenly etched in the etching process, resulting in a decrease in uniformity.

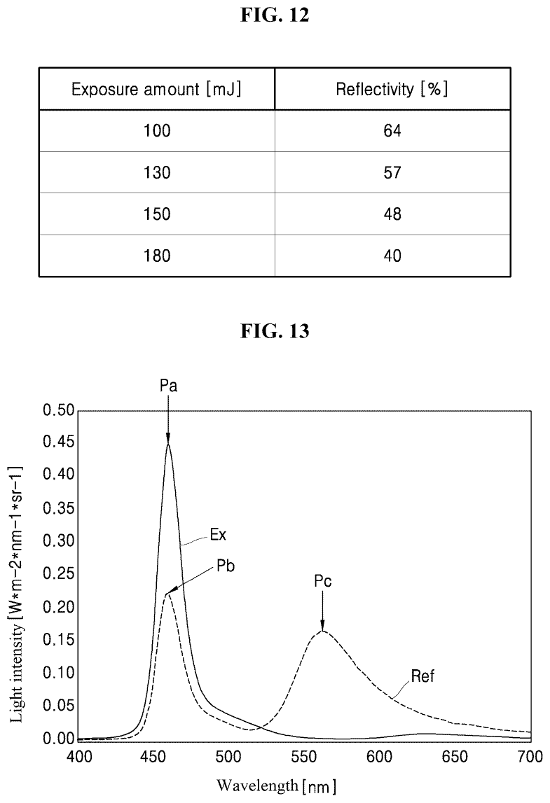

FIG. 13 is a graph illustrating a light-emitting spectrum of the third sub-pixel according to another embodiment of the invention. In FIG. 13, the horizontal axis represents the wavelength of light (nm) and the vertical axis represents the intensity of light (W*m−2*nm−1*sr−1). The intensity of light is a value expressed as a relative value with respect to the maximum value of the light-emitting spectrum. For example, the intensity value of light may be an energy value emitted over a wavelength range of 1 nanometer nm, within a three-dimensional angle of 1 steradian (sr).

FIG. 13 shows the first light-emitting spectrum Ex of the third sub-pixel according to another embodiment of the invention and the second light-emitting spectrum Ref of the third sub-pixel according to the comparative example. For example, the first light-emitting spectrum Ex can be observed in the third sub-pixel in which the active part of the cavity control layer is disposed, and the second light-emitting spectrum Ref can be observed in the third sub-pixel in which the active part of the cavity control layer is not disposed. Both the first light-emitting spectrum Ex and the second light-emitting spectrum Ref may be obtained from a light-emitting layer in which two stacks are laminated.

It can be confirmed that the first light-emitting spectrum Ex only shows the main light-emitting peak Pa. The main light-emitting peak Pa appears in the wavelength range of 400 nm to 495 nm. Thus, the third sub-pixel can emit blue light by the first light-emitting spectrum Ex. It may be confirmed that the main light-emitting peak Pb and the sub light-emitting peak Pc appear together in the second light-emitting spectrum Ref. The main light-emitting peak Pb of the second light-emitting spectrum Ref appears in the wavelength range of 400 nm to 495 nm, and the sub light-emitting peak Pc appears in the wavelength range of 590 nm to 680 nm.

The sub light-emitting peak Pc of the second light-emitting spectrum Ref may be a noise peak. The noise peak may reduce the purity of the color emitted from the main light-emitting peak Pb. As a result, the third sub-pixel in which the active portion of the cavity control layer is not disposed may have the reduced color purity of blue light by the second light-emitting spectrum Ref.

In contrast to this, the first light-emitting spectrum Ex exhibits only the main light-emitting peak Pa, so it is possible to prevent the decrease of the purity of the color. For example, it is worth pointing out that the main light-emitting peak Pa of the first light-emitting spectrum Ex is implemented in a narrow and pointed shape. As the width of the main light-emitting peak Pa becomes narrower and sharper, contamination (or color mixing) caused by adjacent colors does not occur and thus, the color of the emitted light can have a high purity. When the color purity is improved, the color reproduction range can be improved, and the color can be expressed consistently while being rarely affected by changes in brightness. Consequently, according to an embodiment of the invention, it is possible to prevent a decrease in the color reproducibility of the third sub-pixel in which the active portion of the cavity control layer is disposed.

Further, it is worth pointing out that the main light-emitting peak Pa of the first light-emitting spectrum Ex has a light intensity equal to or greater than twice that of the main light-emitting peak Pb of the second light-emitting spectrum Ref. Thereby, the light efficacy of the third sub-pixel in which the active portion of the cavity control layer is disposed can be improved.

According to one or more embodiments of the invention, it is possible to emit blue light without using a color filter, by controlling, through a microcavity effect, light emitted from a light-emitting element, which has a specific wavelength.

According to one or more embodiments of the invention, a display apparatus can omit the color filter for blue light, so it is possible to prevent that a portion of light is lost while passing through the color filter, thereby achieving an effect of improving light efficacy.

According to one or more embodiments of the invention, there is an effect of selectively emitting light in a specific wavelength range by disposing an active portion of the cavity control layer at a location corresponding to a sub-pixel for emitting blue light.

According to one or more embodiments of the invention, by disposing the active portion of the cavity control layer at a location corresponding to the sub-pixel for emitting blue light to strongly emit blue light, it is possible to achieve an effect of improving color purity and color reproduction range.

According to one or more embodiments of the invention, there is an effect of reducing the number of stacks constituting the light-emitting layer of the light-emitting device, thereby allowing a decrease in the driving voltage at the same amount of current, thereby reducing power consumption.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display apparatus comprising:
a substrate including a plurality of sub-pixels;
a first electrode disposed in each of the sub-pixels;
a light-emitting layer disposed on the first electrode;
a second electrode disposed on the light-emitting layer; and
a cavity control layer disposed between the first electrode and the substrate,
wherein the cavity control layer includes a first portion located corresponding to one of the sub-pixels and including a reflective electrode, and a second portion including a transparent layer.

2. The display apparatus of claim 1, wherein the first portion and the second portion of the cavity control layer are disposed on a same plane.

3. The display apparatus of claim 1, wherein:
the sub-pixel includes:
a first sub-pixel configured to emit light of a first color;
a second sub-pixel configured to emit light of a second color different from the first color;
a third sub-pixel configured to emit light of a third color different from the first color and the second color; and
a fourth sub-pixel configured to emit light of white color different from the first to third colors, and
the first portion of the cavity control layer is disposed corresponding to the third sub-pixel.

4. The display apparatus of claim 3, further comprising:
a first color filter disposed corresponding to the first sub-pixel; and
a second color filter disposed corresponding to the second sub-pixel.

5. The display apparatus of claim 1, wherein the light-emitting layer includes stacks laminated in two or less layers, each stack including a hole transporting layer, an organic light-emitting layer, and an electron transporting layer.

6. The display apparatus of claim 5, wherein the light-emitting layer includes:
a first stack including a first common layer, a first light-emitting material layer, and a second common layer;
a second stack including a third common layer, a second light-emitting material layer, a third light-emitting material layer, and a fourth common layer; and
a first charge generation layer disposed between the second common layer of the first stack and the third common layer of the second stack.

7. The display apparatus of claim 1, wherein each of the first portion and the second portion of the cavity control layer includes photocatalytic transition metal oxide.

8. The display apparatus of claim 7, wherein the photocatalytic transition metal oxide includes mixture molecules, the mixture molecules comprising metal molecules bonded to a plurality of functional groups included in photoisomerization diarylethene molecules.

9. The display apparatus of claim 8, wherein the metal molecules include aluminum (Al), silver (Ag), gold (Au), copper (Cu), titanium (Ti), germanium (Ge), or silicon (Si).

10. The display apparatus of claim 8, wherein:
the first portion of the cavity control layer comprises aggregated metal molecules of adjacent mixture molecules contained in the photocatalytic transition metal oxide, to which light is irradiated; and
the second portion comprises desorbed metal molecules from the mixture molecules.

11. The display apparatus of claim 1, wherein the first portion has a reflectivity in a range of substantially 40% to substantially 64% of a light incident on the first portion.

12. The display apparatus of claim 1, wherein:
the substrate includes a first surface and a second surface opposite to the first surface;
the first electrode, the light-emitting layer, the second electrode, and the cavity control layer are disposed in an upper side of the first surface; and
the second surface of the substrate is a light-emitting surface from which light emitted from the light-emitting layer is emitted to the outside.

13. The display apparatus of claim 1, wherein the cavity control layer has a thickness in a range of substantially 450 Å to substantially 550 Å.
